(19) United States
(12) Patent Application Publication
(10) Pub. No.: US 2007/0246763 A1
(43) Pub. Date: Oct. 25, 2007

(54) TRENCH STEP CHANNEL CELL TRANSISTOR AND MANUFACTURE METHOD THEREOF

(75) Inventor: Chao-Hsi Chung, Hsinchu County (TW)

Correspondence Address: GROSSMAN, TUCKER, PERREAULT & PFLEGER, PLLC, 55 SOUTH COMMERICAL STREET, MANCHESTER, NH, 03101, US

(73) Assignee: PROMOS TECHNOLOGIES INC., HSINCHU (TW)

(21) Appl. No.: 11/460,346

(22) Filed: Jul. 27, 2006

(30) Foreign Application Priority Data
Apr. 19, 2006 (TW) 095114008

(51) Int. Cl. H01L 29/78; H01L 21/336

(52) U.S. Cl. 257/301; 438/243; 438/286; 257/329

(57) ABSTRACT

A trench step channel cell transistor and a manufacture method thereof are disclosed. The transistor could be applied to increase the channel length thereof. The transistor comprises a step silicon layer formed by a selective growth, while the step silicon layer is located above the active area of the transistor.

This application claims priority to Taiwan Patent Application No. 095114008 filed on Apr. 19, 2006.

### CROSS-REFERENCES TO RELATED APPLICATIONS

Not applicable.

### BACKGROUND OF THE INVENTION

1. Field of the Invention

The subject invention relates to a trench step channel cell transistor and a manufacturing method thereof. In particular, the invention relates especially to a trench step channel cell transistor that has a step silicon layer formed by selective growth and a manufacturing method thereof.

2. Descriptions of the Related Art

During the industrial revolution of the nineteenth century, machines were mainly used to save man power. In the twentieth century, computers further resolved the demand of more man power. In 1947, W. Schockley, et al. invented the transistor to replace the vacuum tube amplifier that lead the development of microelectronic technology. At the end of the twentieth century, the developments of microminiatures in the electronic technology extensively reduced the volume of electronic devices. In view of the increase in semiconductor circuit integration, the size of the semiconductor devices should be reduced accordingly. At present, electronic materials and processing occur at nanometer sizes. Thus, the standard required for efficiency is raised.

Regarding the short channel effect resulting from the decrease of the current channel length due to the reduction of the size of semiconductor devices, utilizing a recess channel array transistor or a step transistor array was created to increase the length of the current channel. However, there is a drawback to manufacturing a device structure that has a deep trench capacitor like the above. That is, leakage may occur because of the punch-through phenomenon resulting from the diffusion of the buried strap in the deep trench capacitor.

Lim, S.-H., et al have done relevant studies on the growth rate and temperature of the isotropic and anisotropic selective epitaxial growth (see the article “Isotropic/anisotropic selective epitaxial growth of Si and SiGe on LOCOS patterned Si(100) substrate by cold wall type UHV-CVD,” Microprocesses and Nanotechnology Conference, 2002, Digest of Papers. Microprocesses and Nanotechnology 2002, 2002 International 6-8 Nov. 2002 Page(s):74-75). In the studies, Lim, et al found that when the operating temperature is 600° C., the anisotropic selective epitixial growth is very close to a single orientation epitaxial growth. On the other hand, when the operating temperature is 650° C., single orientation epitaxial growth with complete selectivity is achieved. However, the selective epitaxial growth manner has never been utilized in the process for providing a channel in a transistor.

Given the above, it is desired to increase the channel length of the transistor while reducing the leakage resulting from the punch-through phenomenon.

### SUMMARY OF THE INVENTION

In view of the above problems, one object of the subject invention is to provide a trench step channel cell transistor to increase the channel length formed in the transistor and reduce the probability of the occurrence of leakage resulting from the punch-through phenomenon.

The subject invention provides a method for manufacturing a trench step channel cell transistor. The method first provides a substrate that has a trench capacitor and an active area corresponding to the trench capacitor. Thereafter, an anisotropic step silicon layer is deposited above the active area. Preferably, the anisotropic step silicon layer is a single orientation silicon layer formed by selective epitaxial growth.

According to a preferred embodiment of the subject invention, the aforementioned method for manufacturing the trench step channel cell transistor comprises depositing a first sacrificial oxide layer on the active area of the substrate, patterning the sacrificial oxide layer to expose a first predetermined area of the active area and to cover a second predetermined area of the active area, and forming an anisotropic step silicon layer above the active area. Preferably, the anisotropic step silicon layer is a single orientation silicon layer formed by selective epitaxial growth.

According to another preferred embodiment of the subject invention, the aforementioned method for manufacturing a trench step channel cell transistor further comprises removing a portion of the first sacrificial oxide layer from the second predetermined area after the formation of the step silicon layer.

According to yet another preferred embodiment of the subject invention, the aforementioned method for manufacturing a trench step channel cell transistor further comprises depositing a second sacrificial oxide layer on the substrate that has the trench capacitor, implanting ions into the substrate, and removing the second sacrificial oxide layer, after the removal of a portion of the first sacrificial oxide layer from the second predetermined area.

According to another preferred embodiment of the subject invention, the aforementioned method for manufacturing a trench step channel cell transistor comprises depositing a gate insulating layer on the substrate, and forming a gate electrode above the gate insulating layer to cover a portion of the active area and the step silicon layer, after the removal of the second sacrificial oxide layer.

According to another preferred embodiment of the subject invention, the first sacrificial oxide layer has a thickness that ranges from about 40 Å to about 50 Å.

According to yet another preferred embodiment of the subject invention, the gate electrode comprises a polysilicon layer, a tungsten silicide layer, and a silicon nitride layer, in the aforementioned method for manufacturing a trench step channel cell transistor.

The subject invention provides a trench step channel cell transistor formed in a substrate having a trench capacitor. The transistor comprises an active area, a gate electrode, a first source/drain, a dielectric layer, and a second source/drain. The active area is located in the substrate and corresponds to the trench capacitor. A step silicon layer is located above the active area such that a step channel is formed under the gate electrode. The dielectric layer is interposed between the gate electrode and the active area, and between the gate electrode and the step silicon layer. The gate electrode is located above the substrate and adjacent to the trench capacitor. The first source/drain is located in the substrate under the first side of the gate electrode and electrically connects with the trench capacitor. The second source/drain is located in the step silicon layer that is located above the substrate, and is under the second side of the gate electrode opposite to the trench capacitor. The transistor of the subject invention can provide a step channel connecting the first source/drain and the second source/drain.

According to one preferred embodiment of the aforementioned trench step channel cell transistor of the subject invention, the material of the dielectric layer is selected from a group consisting of silicon oxide, silicon nitride, silicon oxynitride, or a combination thereof.

According to one preferred embodiment of the subject invention, the trench capacitor in the substrate on which the aforementioned trench step channel cell transistor is formed has a deep trench structure and further comprises a first electrode, an insulating layer, and a second electrode. The first electrode is located in the substrate and surrounds the deep trench structure. The insulating layer is located on the sidewall and bottom of the deep trench structure. The second electrode fills in the deep trench structure and sandwiches the insulating layer with the first electrode.

According to one preferred embodiment of the subject invention, the step silicon layer is formed by selective epitaxial growth in the aforementioned trench step channel cell transistor.

According to one preferred embodiment of the subject invention, anisotropic growth is the selective epitaxial growth used to form the step silicon layer in the aforementioned trench step channel cell transistor.

According to one preferred embodiment of the subject invention, the trench capacitor in the substrate on which the aforementioned trench step channel cell transistor is formed further comprises a buried strap, which is located in the deep trench structure and directly comes into contact with the substrate such that the second electrode electrically connects with the first source/drain of the transistor.

According to one preferred embodiment of the subject invention, the gate electrode comprises a polysilicon layer, a tungsten silicide layer, and a silicon nitride layer in the aforementioned trench step channel cell transistor.

According to one preferred embodiment of the subject invention, the aforementioned trench step channel cell transistor further comprises a pair of insulating spacers on the sidewall of the gate electrode.

The anisotropic step silicon layer of the transistor of the subject invention is used to increase the length of a channel formed in the transistor. Because the anisotropic step silicon layer is formed by a single orientation epitaxial growth with complete selectivity, not only is the channel distance between the source and the drain increased, but also the probability of the occurrence of leakage resulting from the punch-through phenomenon is reduced.

### BRIEF DESCRIPTION OF THE DRAWINGS

FIG. 1 shows an embodiment of the trench step channel cell transistor of the subject invention.

FIG. 2 shows a top view of a substrate that has an active area, a shallow trench isolation structure, and a trench capacitor.

FIG. 3 is a top view showing a photoresist located on the first sacrificial oxide and partially covering the active area and shallow trench isolation structure.

FIG. 4 is a top view showing the first sacrificial oxide formed on the active area.

FIG. 5 is a top view showing the formation of an anisotropic step silicon layer.

FIG. 6 is a cross-section view showing the formation of a gate oxide.

FIG. 7 is a cross-section view showing a gate electrode deposited on the gate insulating layer.

FIG. 8 is a top view showing a formed gate electrode.

FIG. 9 is a cross-section view showing a bit contact window located on the anisotropic step silicon layer.

### DESCRIPTION OF THE PREFERRED EMBODIMENT

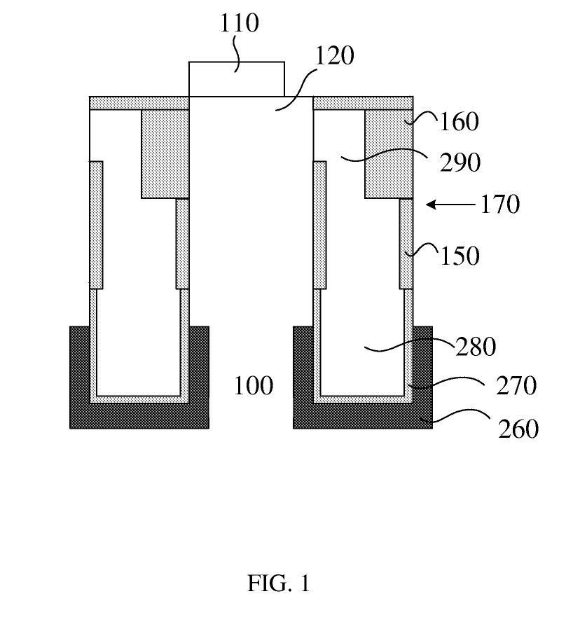

FIG. 1 is a schematic diagram showing the related location of each element contained in a trench step channel cell transistor according to the subject invention. The trench step channel cell transistor primarily contains a step silicon layer 110 and an active area 120 in a substrate 100. The substrate 100 has a trench capacitor 170, which has a deep trench structure and comprises a first electrode 260, an insulating layer 270, a second electrode 280, and a buried strap 290.

As shown in FIG. 1, the step silicon layer 110 is located above the active area 120. The trench capacitor 170 is located in the substrate 100. The first electrode 260 is located in the substrate 100 and surrounds the lower portion of the trench capacitor 170. The insulating layer 270 is located on the sidewall and on the bottom of the trench capacitor 170. The second electrode 280 is filled in the trench capacitor 170 and sandwiches the insulating layer 270 with the first electrode 260. The buried strap 290 is located in the trench capacitor 170 and directly comes into contact with the substrate 100 such that the second electrode 280 electrically connects with the first source/drain of the transistor.

One characteristic of the subject invention lies in the step silicon layer that is an anisotropic step silicon layer. Preferably, the anisotropic step silicon layer is formed by a single orientation epitaxial growth with selectivity. The anisotropic step silicon layer not only increases the channel length formed between the source and the drain but also reduces the probability of the occurrence of leakage resulting from the punch-through phenomenon. As will be described below, one example is illustrated to describe the method for manufacturing the trench step channel cell transistor of the subject invention. The steps of the method can be respectively referred to the figures.

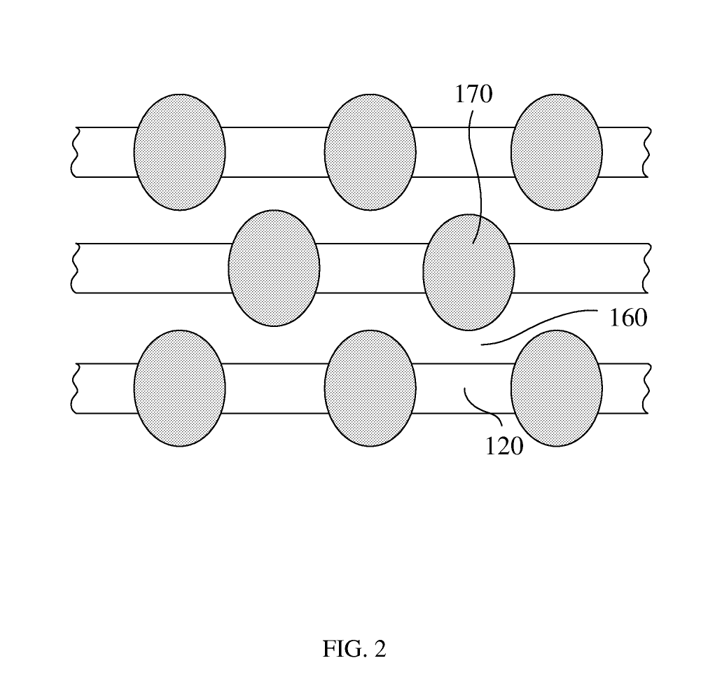

Referring to FIG. 1 and FIG. 2, FIG. 2 shows a top view before the anisotropic step silicon layer 110 depicted in FIG. 1 has been formed, illustrating a memory array of the subject invention. The method for manufacturing each memory unit of the subject invention first provides a substrate that has at least one trench capacitor and an active area corresponding to the trench capacitor. As shown in FIG. 1, each memory unit comprises an active area 120, a shallow trench isolation structure 160 and a trench capacitor 170. The trench capacitor 170 has a deep trench structure and comprises a collar oxide layer 150 and a buried strap 290. The collar oxide layer 150 is located on the sidewall of the trench capacitor 170. The active area 120 and the shallow trench isolation structure 160 are adjacent to each other. The trench capacitor 170 is separately arranged between the active areas 120. It should be mentioned that the manufacturing processes for forming the collar oxide layer 150, the shallow trench isolation structure 160, and the trench capacitor 170 are known technology and can be referred to in the prior art publications such as in Taiwan Patent Publication No. 1231968.

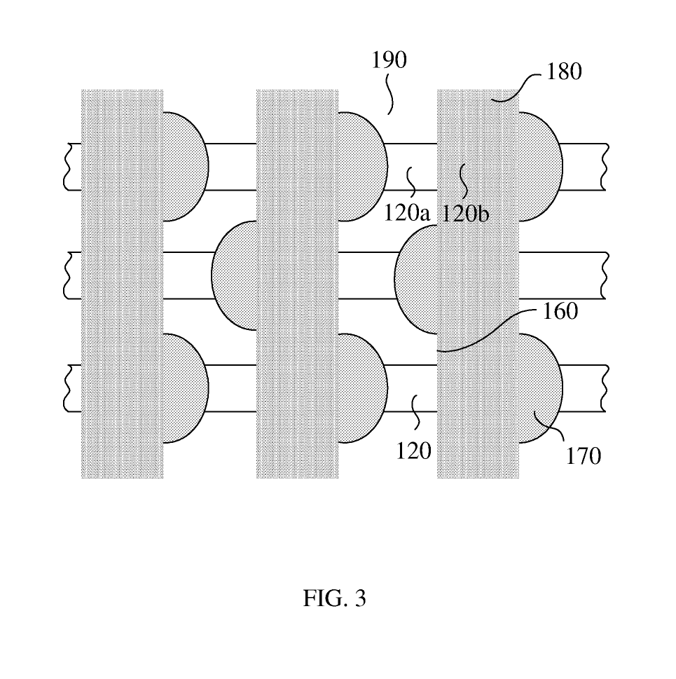

Thereafter, a first sacrificial oxide layer 190 is deposited on the substrate 100. The first sacrificial oxide has a thickness ranging from about 40 Å to about 50 Å. Then, referring to FIG. 3, a mask 180 is provided on the first sacrificial oxide layer 190, partially covering the active area 120 and the shallow trench isolation structure 160. Specifically, the mask 180 exposes a portion of the first sacrificial oxide layer 190 that covers a first predetermined area 120a of the active area 120, and the unexposed portion of the first sacrificial oxide layer 190 covers a second predetermined area 120b of the active area 120. The second predetermined area 120b connects with the corresponding trench capacitor 170.

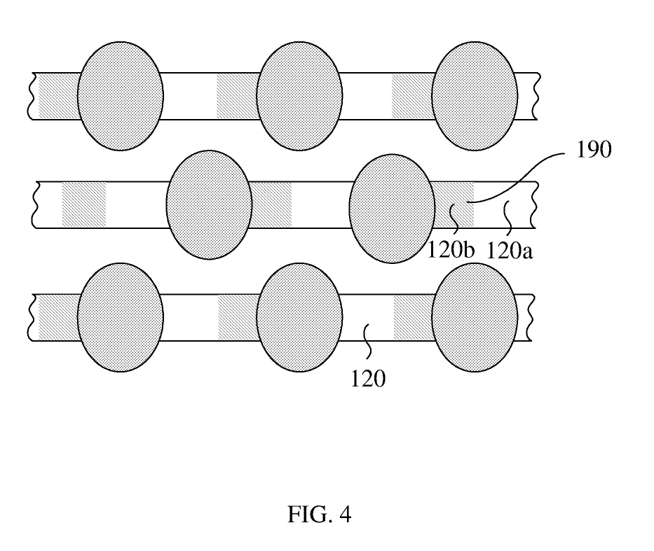

Referring to FIG. 3 in combination with FIG. 4, the mask 180 depicted therein is a patterned mask. A portion of the first sacrificial oxide 190 exposed by the mask 180 is etched to expose the first predetermined area 120a on the active area 120. After, the patterned mask 180 is removed to expose the remained portion of the first sacrificial oxide 190 that covers the second predetermined area 120b on the active area 120.

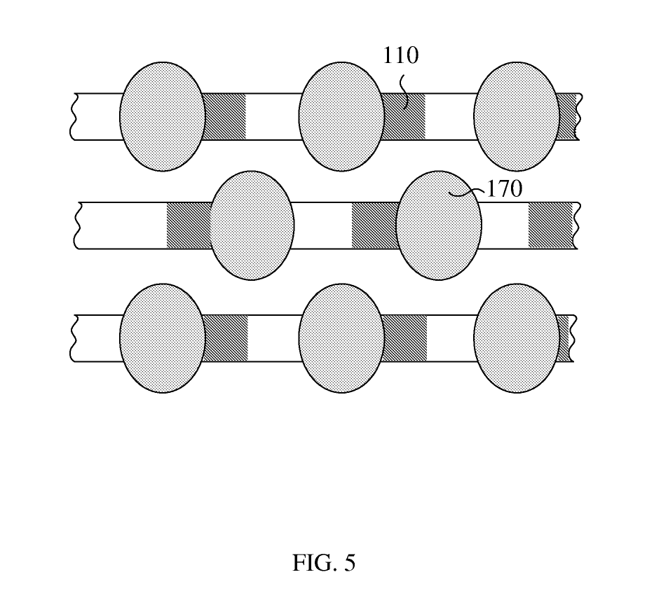

FIG. 5 shows the use of the remained portion of the first sacrificial oxide layer 190 as a mask to form an anisotropic step silicon layer 110 on the first predetermined area 120a by selective growth. Preferably, the anisotropic step silicon layer is a single orientation silicon layer formed with selective epitaxial growth. Afterwards, the first sacrificial oxide layer 190 is removed and a second sacrificial oxide layer (not shown) is deposited on the substrate 100. The second sacrificial oxide layer is then used as a mask for implanting ions into the active area 120 of substrate 100 and the step silicon layer 110 to adjust the working voltage of area 120. After the ion implantation, the second sacrificial oxide layer is removed.

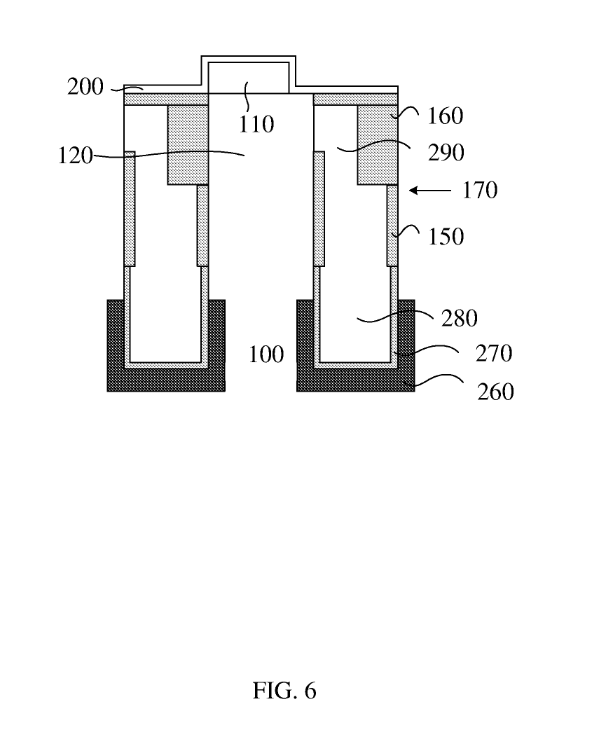

In FIG. 6, after removing the second sacrificial oxide layer, a gate insulating layer 200 is deposited onto the substrate 100. The gate insulating layer 200 can be formed by depositing a gate dielectric layer. The material of the dielectric layer is selected from a group consisting of silicon dioxide, silicon nitride, silicon oxynitride, and a combination thereof.

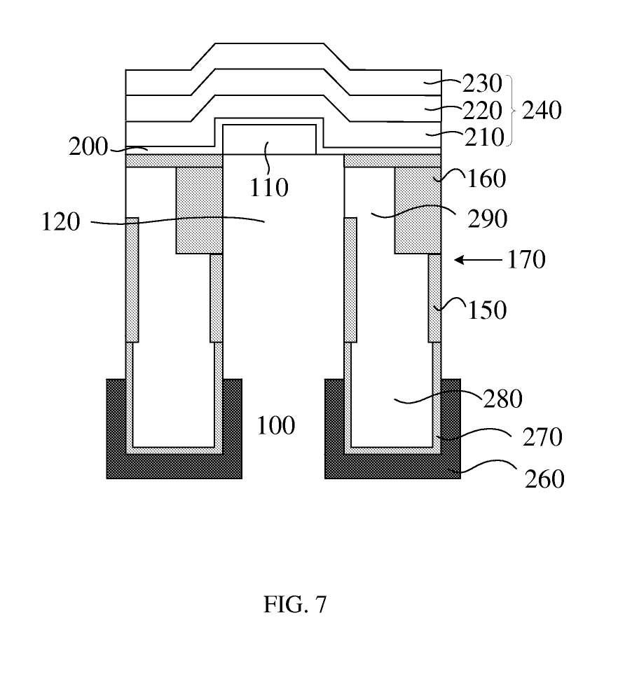

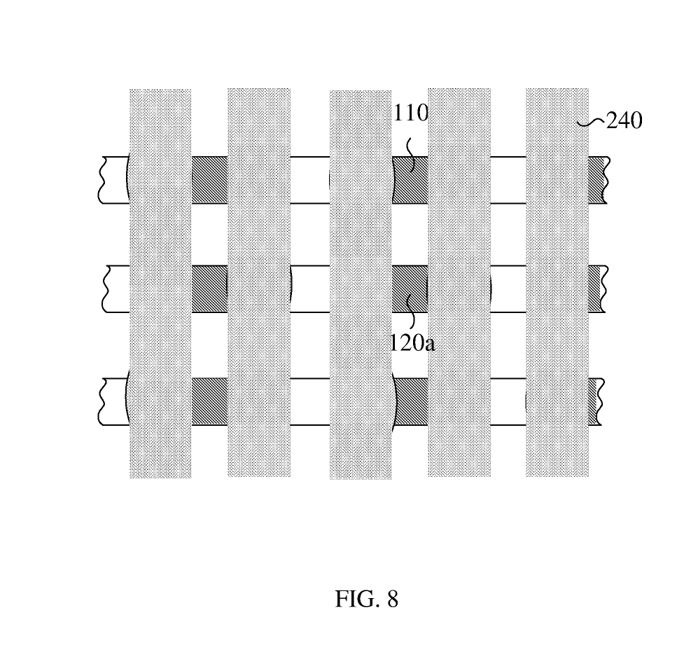

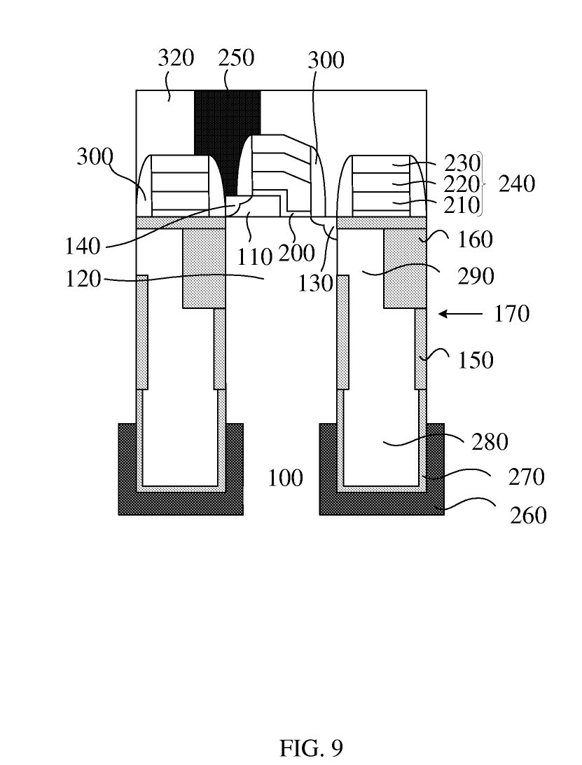

Referring to FIG. 7, a gate electrode 240 is formed on the gate insulating layer 200 to cover the active area 120 and step silicon layer 110. In this embodiment, the step of forming the gate electrode 240 comprises sequentially depositing a polysilicon layer 210, a tungsten silicide layer 220 and a silicon nitride layer 230, and thus forms the cross-section view depicted in FIG. 7. Afterwards, a gate electrode 240 is finally formed above a portion of the active area 120 and a portion of the step silicon layer 110 by using proper developing and etching processes. A configuration of thus formed gate electrode 240 is shown in FIGS. 8 and 9, with FIG. 8 representing the top view. Nonetheless, the abovementioned is a preferred embodiment only of the subject invention, but is not intended to limit the composition of the gate electrode 240 and the arrangement order of the metal layer(s) thereof.

After forming a gate electrode 240, a spacer is formed. That is, a pair of insulating spacers 300 are formed on the sidewall of the gate electrode 240. Afterwards, an ion doping process is conducted to form a first source/drain 130 in the active area 120 and a second source/drain 140 in the step silicon layer 110. The first source/drain 130 electrically connects with the trench capacitor 170. Particularly, the first source/drain 130 is located in the substrate 100 under the first side of the gate electrode 240 and electrically connects with the buried strap 290 of the trench capacitor 170. The second source/drain 140 is located in the step silicon layer 110 that is above the substrate 100, and is under the second side of the gate electrode 240 opposite to the trench capacitor 170. The trench step channel formed in the transistor unit of the subject invention is located above a portion of the substrate 100 and a portion of the upper surface and the sidewall of the step silicon layer 110. The channel connects the first source/drain 130 and the second source/drain 140 to increase the length of the current channel and resolve the leakage problem resulting from the punch-through phenomenon occurring in conventional recess channel array transistors.

Lastly, a series of processes, such as forming an insulating layer 320, patterning by using a photoresist, and etching, are executed to form the structure depicted in the cross-sectional view of FIG. 9. These processes are known techniques, and thus are not further described herein. Moreover, it should be mentioned that a bit contact window 250 is located above the step silicon layer 110 and is used to contact a bit line (not shown). Therefore, the subject invention further provides a raised second source/drain 140 such that the formation of the bit contact window 250 is easier.

As compared with the prior technology, the trench step channel cell transistor of the subject invention utilizes the anisotropic selective epitaxial growth to deposit silicon on the active area of the transistor and increase the length of the current channel with a step channel. Moreover, the superiority of the transistor of the subject invention over conventional recess channel array transistors lies in providing a trench step channel that is located above the active area of the transistor. Accordingly, the leakage resulting from the punch-through phenomenon that occurs in conventional recess channel array transistors can be reduced. In other words, the leakage resulted from the diffusion of the buried strap due to the recess channel can be prevented. Moreover, the method disclosed in the subject invention can also resolve the problem of sub-threshold voltage and enhance the performance of the cell transistor.

As known by persons skilled in the art, the above disclosure is just related to preferred embodiments of the subject invention and is not intended to limit the scope of the claims. Other equivalent changes or modifications without departing from the spirit disclosed in the subject invention should be covered in the following claims as appended.

What is claimed is:

1. A method for manufacturing a trench step channel cell transistor, comprising the steps of:
providing a substrate having at least one trench capacitor and an active area corresponding to the trench capacitor;
depositing a first sacrificial oxide layer on the active area of the substrate;
patterning the first sacrificial oxide layer to expose a first predetermined area of the active area and to cover a second predetermined area of the active area, the second predetermined area connecting with the trench capacitor corresponding thereto;
selectively forming a step silicon layer on the first predetermined area;
removing a portion of the first sacrificial oxide layer from the second predetermined area;
depositing a gate insulating layer on the substrate; and
forming a gate electrode on the gate insulating layer to cover a portion of the active area and the step silicon layer.

2. The method of claim 1, wherein the step of patterning the first sacrificial oxide comprises:
forming a patterned mask on the first sacrificial oxide layer;
etching the first sacrificial oxide layer to expose the first predetermined area of the active area; and
removing the patterned mask to expose the first sacrificial oxide layer of the second predetermined area of the active area.

3. The method of claim 1, wherein the first sacrificial oxide has a thickness ranging from about 40 Å to about 50 Å.

4. The method of claim 1, wherein after the removal of a portion of the first sacrificial oxide layer, the method further comprises:
depositing a second sacrificial oxide layer on the substrate having the trench capacitor;
implanting ions into the substrate; and
removing the second sacrificial oxide layer.

5. The method of claim 1, wherein the step of selectively forming the step silicon layer comprises depositing an anisotropic step silicon layer by selective epitaxial growth to form a single orientation silicon layer.

6. The method of claim 1, wherein after the step of forming the gate electrode, the method further comprises forming a pair of insulating spacers on the sidewall of the gate electrode.

7. The method of claim 1, wherein after forming the gate electrode, the method further comprises forming a first source/drain in the active area and forming a second source/drain in the step silicon layer, wherein the first source/drain electrically connects with the trench capacitor.

8. The method of claim 1, wherein the step of forming the gate electrode comprises depositing a polysilicon layer, a tungsten silicide layer, and a silicon nitride layer.

9. A transistor having a trench step channel structure, formed on a substrate with a trench capacitor structure therein, and comprising:
a gate electrode above the substrate and adjacent to the trench capacitor;
a first source/drain in the substrate under a first side of the gate electrode and electrically connecting with the trench capacitor;
an active area in the substrate and corresponding to the trench capacitor;
a step silicon layer above the active area;
a dielectric layer interposed between the gate electrode and the active area; and
a second source/drain in the step silicon layer and located above the substrate under a second side of said gate electrode opposite to the trench capacitor,
thereby a step channel is provided to connect the first source/drain and the second source/drain.

10. The transistor of claim 9, wherein the trench capacitor has a deep trench structure and further comprises:
a first electrode in the substrate and surrounding the deep trench structure;
an insulating layer located on the sidewall and bottom of the deep trench structure; and
a second electrode filled in the deep trench structure and sandwiching the insulating layer with the first electrode.

11. The transistor of claim 9, wherein the step silicon layer is formed by selective epitaxial growth.

12. The transistor of claim 11, wherein the selective epitaxial growth is an anisotropic growth.

13. The transistor of claim 10, wherein the trench capacitor further comprises a buried strap in the deep trench structure and directly contacts the substrate such that the second electrode electrically connects with the first source/drain of the transistor.

14. The transistor of claim 9, wherein the gate electrode comprises a polysilicon layer, a tungsten silicide layer, and a silicon nitride layer.

15. The transistor of claim 9, further comprising a pair of insulating spacers on the sidewall of the gate electrode.
